(19) United States
(12) Patent Application Publication
(10) Pub. No.: US 2008/0253414 A1
(43) Pub. Date: Oct. 16, 2008

(54) VCSEL DRIVER

(75) Inventor: Andreas Bock, Hemmingen (DE)

Correspondence Address: TEXAS INSTRUMENTS INCORPORATED, P O BOX 655474, M/S 3999, DALLAS, TX, 75265, US

(73) Assignee: TEXAS INSTRUMENTS DEUTSCHLAND GMBH, Freising (DE)

(21) Appl. No.: 12/054,183

(22) Filed: Mar. 24, 2008

(30) Foreign Application Priority Data
Mar. 22, 2007 (DE) 10 2007 013 820.4

(51) Int. Cl. H01S 5/042

(52) U.S. Cl. 372/29.012

(57) ABSTRACT

The invention provides a driver for a semiconductor light emitting device, in particular a vertical cavity surface emitting laser (VCSEL) which includes a delay buffer for generating an output signal as a delayed version of an input signal; a pulse generation stage coupled in parallel with the delay buffer and adapted to produce selectively positive and negative output pulses starting concurrently with respective positive and negative edges of the output signal of the buffer; and a summer for summing the output signal and the pulses.

This application claims priority from German Patent Application No. 10 2007 013 820.4, filed 22 Mar. 2007.

### FIELD OF THE INVENTION

The invention relates to a driver for a semiconductor light emitting device, more specifically to a vertical cavity surface emitting laser.

### BACKGROUND

VCSEL (Vertical Cavity Surface Emitting Laser) diodes are often used as light emitting semiconductor devices. A VCSEL's circular beam is easily coupled with a fiber. This is mainly due to the characteristic of VCSEL diodes as a surface emission rather than edge emission device and they are known for their excellent power efficiency and durability. Accordingly, VCSEL diodes are widely used in low cost optical transmission systems. However, in high data rate transmission systems, the VCSEL diodes have some drawbacks. For the typical driving circuits, the VCSEL diodes represent a significantly high capacitance, and the asymmetric turn on and turn off behavior often results in asymmetric optical eye plots. An illustrative example of such an asymmetric optical eye plot is shown in FIG. 1A. In order to optimize the bit error rate of the optical transmission link, it is desired to maximize the horizontal and vertical opening of the optical eye plot, i.e., to make the optical eye plot more symmetric. Existing VCSEL drivers therefore introduce output current peaking for steeper optical edges and a threshold adjustment capability in order to correct the eye's crossing point. Both enhancements increase the eye opening, but they fail to render the optical output eye more symmetric. An illustrative example for a symmetric optical eye plot is shown in FIG. 1B. A symmetric optical output eye represents the optimal solution for maximization of vertical and horizontal eye opening, thereby minimizing the bit error rate.

Theoretical and experimental studies have shown that symmetric optical eyes can be achieved by driving the VCSEL diode with a pre-distorted current signal showing single-sided or asymmetric current peaking. Such a solution is, for example, described in Kucharski, et al., “A 20 Gb/s VCSEL Driver with Pre-Emphasis and Regulated Output Impedance in 0.13 um CMOS,” IEEE ISSCC, pp. 222-223, February 2005. This prior art solution superimposes a current peak to the tail current of the output driver, thereby creating an undershoot on its output signal. Both the width and the height of the undershoot are fixed. The width of the undershoot is limited to the bit width of the input signal. By superimposing the peak current onto the driver's tail current, the output common mode and the crossing point of the output eye are shifted. Due to its single-sided and fixed peak value implementation, this solution does not allow a flexible adjustment to accommodate different data rates and different VCSEL diode parameters, and to compensate the influence of the transmit optical sub assembly.

### SUMMARY

It is an object of the invention to provide a driver for a light emitting semiconductor device, such as, for example, a VCSEL diode, capable of optimizing the optical eye plot for data transmission.

A driver according to an embodiment of the invention includes a delay buffer for generating an output signal as a delayed version of an input signal; a pulse generation stage coupled in parallel to the delay buffer and adapted to produce selectively positive and negative output pulses starting concurrently with respective positive and negative edges of the output signal of the buffer; and summing circuitry for summing the output signal and the pulses. The driver according to such embodiment of the invention is capable of generating over- and undershoot having a completely independent adjustment of peak width and height for both, the over- and the undershoot. The wave shaping circuitry (driver) comprises two major building blocks: the over- and undershoot pulse generation stage and a buffer connected in parallel to the pulse generation stage. The delay buffer is adapted to apply basically the same signal delay to the input signal as the pulse generation stage, such that the pulses produced by the pulse generation stage occur concurrently with the edges of the input signal. A purpose of the delay buffer is to delay the input signal, to establish a predetermined phase relationship between the output signal of the delay buffer and the output signal of the pulse generation circuit. The delay buffer can also be used to adjust the level of the input signal. The input signal typically has a substantially rectangular alternating waveform. The outputs of both the delay buffer and the pulse generation stage are superimposed, which may be done in a summing of the two output signals (e.g. voltages or currents) to represent the final output signal. The pulse generation stage is adapted to gate short peaks with a controlled width and a controlled height at every edge of the input signal with a fall back to zero in-between the peaks.

The invention may advantageously used for driving VCSEL diodes. However, the driver according to the invention may also be advantageously applied to other kinds of semiconductor light emitting devices.

In one aspect, the pulse generation stage may include a combination of an AND gate, a delay element and an inverter. The delay stage and the inverter may be coupled in series between the input of the pulse generation stage and an input of the AND gate. According to another embodiment of the invention, the pulse generation stage may include an inverter coupled between the input of the pulse generation stage and a first input of a NAND gate, and a delay stage coupled between the input of the pulse generation stage and a second input of the NAND gate. Still another implementation of a pulse generation stage according to the invention may include a NOR gate, an inverter and a delay stage, wherein the inverter is coupled between the input of the pulse generation stage and a first input of the NOR gate, and the delay stage is coupled between the input of the pulse generation stage and a second input of the NOR gate. All the above-mentioned implementations of a pulse generation stage according to the invention and in particular combinations thereof may be used to provide a pulse generation stage according to the invention. Each combination of a logic gate, a delay element and an inverter provides a specific pulse in either the positive of the negative direction. The width of the pulse can be controlled and adjusted by the delay of the delay element. The height of the pulse determined by the supply voltage and additional circuitry such as voltage dividers of equivalent means. In order to produce pulses in positive and negative direction (with respect to a virtual middle potential between the supply voltage and ground), two of the above circuits may be combined. Efficient implementations of each of the logic circuits and a compact and efficient implementation of pulse generation circuitry for generation pulses in positive and negative direction based on the above logic circuits is described below.

Accordingly, a pulse generation stage according to one embodiment of the invention may be coupled and implemented in a differential current mode manner. Such a differential current mode pulse generation stage may include a level shifter, a first pair of transistors, a second pair of transistors, a delay element and a signal inversion stage. The first and the second pair of transistors is coupled so as to provide a logical NAND function for the two differential inputs of the first and the second differential pair. Basically, using a differential current mode architecture provides a very robust solution for high speed applications. Modifying the basic NAND function by merely introducing a delay element and an inversion stage as set out here above constitutes a circuitry being easy to implement and small in terms of chip area. The signal inversion stage is preferably implemented by simply twisting the two differential wires ones, which connect a preceding stage to a following stage. According to one embodiment of the invention, the delay element and the signal inversion stage are coupled in series between the input and the first pair and the output of the level shifter is coupled to the second pair. Another embodiment includes also a level shifter, the first pair and the delay element as well as an inversion stage, which are coupled in series between the output of the level shifter and the second pair for feeding a level shifted, delayed and inverted version of the input signal to the second pair. According to another aspect of the invention, a current source is coupled to an output of the pulse generation stage in order to adjust the common mode level of the differential output signal. The additional current provided by the current source corrects the common mode levels and assures a return to zero output in-between the gate peaks. As each of the above implementations of a level shifter, a delay element, an inversion stage and the two differential pairs of transistors can be used to generate either a positive or a negative pulse, two of the above mentioned implementations are preferably combined for a pulse generation according to the invention.

According to still another embodiment of the invention, the driver further includes a second delay stage, a second signal inversion stage, a third pair of transistors and a fourth pair of transistors. The second delay stage is coupled between the input and the third pair and the second signal inversion stage is coupled between the second pair of transistors and the level shifter. This embodiment of a pulse generation circuit according to the invention produces pulses of two polarities, i.e. positive and negative pulses.

A preferred technology for implementing the invention is a bipolar or BICMOS technology. For bipolar transistors, the logic NAND function is preferably implemented by coupling the collector of one transistor of the second pair to the common emitters of the first pair. The common emitters of the first pair are coupled to a current source (e.g. a biased MOSFET transistor). The collectors of the second pair of transistors are coupled to respective loads (e.g. two resistive elements, one for each transistor) thereby providing differential output nodes between the loads and the collectors. Eventually, the collector of the second transistor of the first pair of transistors is also coupled one output node of the differential output nodes. The level shifter may consist of two bipolar transistors each being coupled to a respective current source (e.g. one biased NMOS transistor per branch). The input signal to be shifted is coupled to the bases of the two bipolar transistors. The shifted output signal can be tapped from wires between the current sources and the emitters of the bipolar transistors.

In order to improve the common mode characteristics of the output pulses additional pairs of transistors may be introduced. If only one of the transistors of the first pair is coupled to the common emitters of the second pairs, the load as well as parasitic elements are different for the two transistors of the first pair. Therefore, it can be useful to couple an additional pair of transistors between the collector of the second transistor of the first pair and the supply voltage. For an implementation of a pulse generation stage for positive and negative pulses, this measure is preferably applied twice. The same considerations apply for the loads of the second pair of transistors. Also in this regard it can be useful to couple the same loads (e.g. resistors or the like having the same dimensions) between the collectors of the second pair (and also fourth pair if present) of transistors and supply voltage. For an implementation having two stages, one for each polarity of a pulse, the output signals may be tapped from one branch of the second pair and the forth pair. This will result in a strictly symmetric circuit and layout having an improved common mode behavior and a better return-to-zero characteristic. Additional current sources coupled to the output nodes in order to adjust the output level are not necessary.

### BRIEF DESCRIPTION OF THE DRAWINGS

Further aspects of the invention will become evident from the below description of specific example embodiments, taken together with the accompanying drawings, wherein:

FIGS. 1A and 1B show an illustrative example of asymmetric and symmetric eye plots of a data eye of an optical data transmission by a VCSEL diode;

FIG. 2 shows a block diagram of a first embodiment of the invention;

FIGS. 3A-3C show three different logical circuits to be used within a pulse generation stage according to the invention;

FIG. 4 shows a current mode NAND gate according to the prior art;

FIG. 5 shows a modified current mode NAND gate according to a first embodiment of the invention;

FIG. 6 shows a modified current mode NAND gate according to a second embodiment of the invention;

FIG. 7 shows waveforms for a pulse generation stage implemented according to the embodiments of FIGS. 5 and 6;

FIG. 8 shows the circuit of FIG. 6 with an additional current source according to an aspect of the invention;

FIG. 9 shows waveforms produced by the circuit shown in FIG. 8;

FIGS. 10A and 10B show waveforms produced by the embodiment of the invention shown in FIG. 8;

FIG. 11 shows a simplified schematic of a pulse generation stage according to the invention;

FIG. 12 shows waveforms relating to the embodiment of the invention shown in FIG. 11; and

FIG. 13 shows more waveforms relating to the embodiment of FIG. 11.

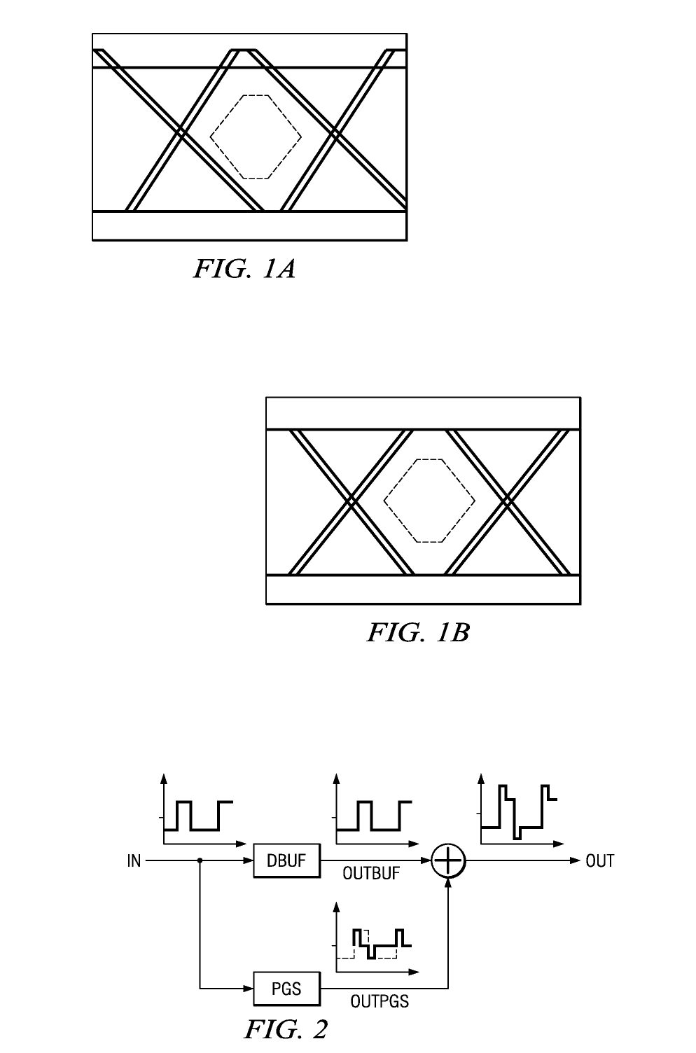

### DETAILED DESCRIPTION OF EXAMPLE EMBODIMENTS

FIG. 2 shows a block diagram of a first embodiment of the invention. A delay buffer DBUF is coupled in parallel with a pulse generation stage PGS. The basic functionality of the shown architecture can be derived from the waveforms indicated at the input node IN and the respective outputs OUTBUF, OUTPGS of the delay buffer DBUF and the pulse generation stage PGS, as well as at the output OUT. The input signal IN at the input node is fed into the delay buffer DBUF and the pulse generation stage PGS. The delay buffer applies a delay to the input signal that compensates the delay the input signal undergoes in the pulse generation stage PGS. The pulse generation stage PGS produces positive and negative pulses concurrently with the rising and falling edges of the output signal of the delay buffer DBUF. The output signal of the delay buffer DBUF is indicated as a dotted line in the waveform diagram at the output of the pulse generation stage PGS. The delayed input signal received at the output of the delay buffer DBUF and the pulse signal generated by the pulse generation stage PGS are summed in a summing stage such that the combined output signal OUT shows the desired over- and undershoot pulses at the rising and falling edges of the delayed input signal. The height and the width of the over- and undershoot pulses can be arbitrarily defined within the pulse generation stage PGS.

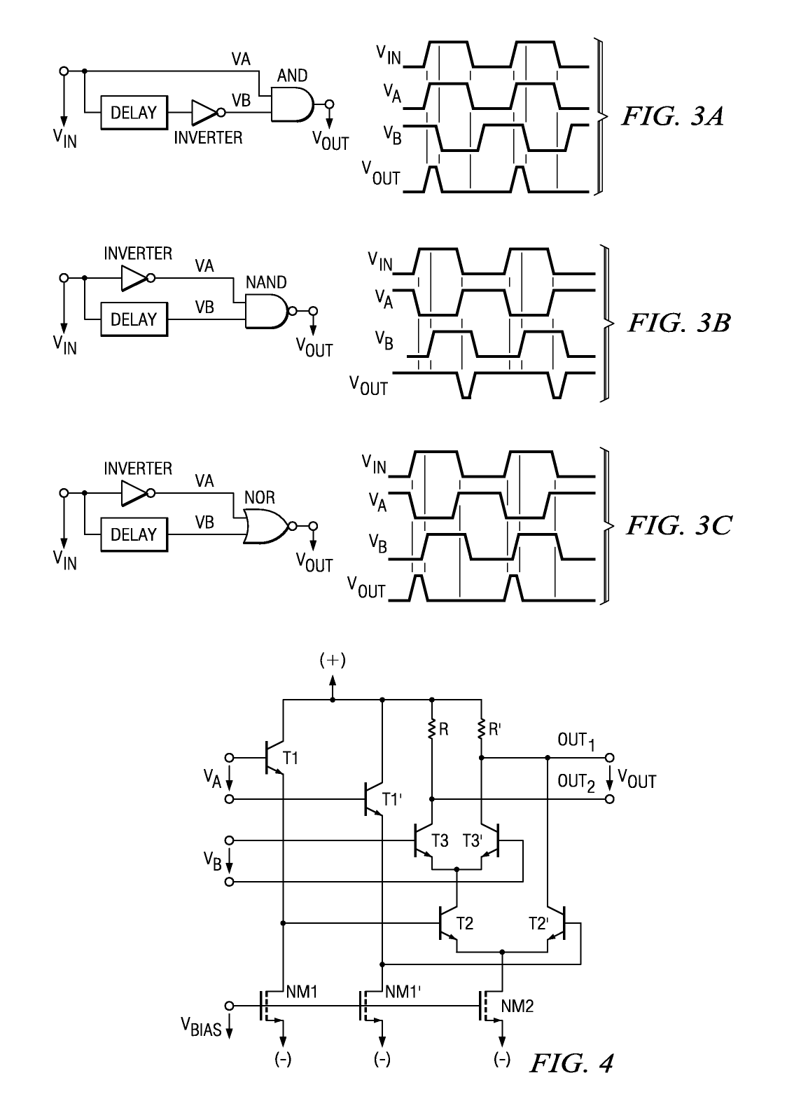

FIGS. 3A-3C show three different circuits, which may be used in the pulse generation stage PGS to produce defined positive or negative pulses. The simplified schematic shown in FIG. 3A includes a delay element DELAY, an inverter INVERTER and a logic AND gate. The input signal VIN is directly passed to one input of the AND gate and the other input of the AND gate receives the input signal VIN through the delay element and the inverter. Accordingly, the second input VB of the AND gate is a delayed and inverted version of the input signal at the other input node VA of the AND gate. The output signal VOUT is a short positive pulse as indicated in the waveforms on the right-hand side of FIG. 3A. The circuit according to the simplified schematic shown in FIG. 3B can be used to produce negative pulses. The inverter INVERTER is coupled to the first input VA of the NAND gate, whereas the delay element DELAY is coupled to the second input VB of the NAND gate. The input signal VIN is passed to both the inverter and the delay element. The output signal VOUT indicated in the waveform representation shows a short negative pulse concurrently with the falling edge of the input signal VIN. Still another architecture for a pulse generation circuitry to be used in the pulse generation stage of the invention is shown in FIG. 3C. Here, the input signal VIN is passed to the inverter INVERTER and to the delay element DELAY. The outputs of the inverter and the delay element are coupled to the two inputs VA and VB of a NOR gate. The output VOUT shows a short positive pulse concurrently with the rising edge of the input signal VIN. For all the embodiments shown in FIGS. 3A-C, the pulse duration is basically defined by the delay introduced by the delay element DELAY. The height of the pulses depends primarily on the supply voltages used for the logic gates shown in FIGS. 3A-C. However, the height of the pulses can be adapted by additional circuitry as, for example, voltage dividers or the like. More details will be apparent from the following description of another embodiment of the invention.

FIG. 4 shows a conventional differential current mode NAND gate. The input signals VA and VB are logically combined to produce the output signal VOUT according to a logic NAND operation. The transistors T1, T1′ serve as level shifters for the input signal VA. The shifted input signal is passed to a first pair of transistors T2, T2′, with the transistor T2 coupled to a second differential pair of transistors T3, T3′ at whose bases the second input signal VB is received. The two transistors T3 and T3′ of the second differential pair are coupled by their collectors to a pair of resistors R, R′ representing the load to the second differential pair T3, T3′. The connecting wires between T3, T3′ and R, R′ represent the output nodes OUT1 and OUT2, respectively. The output voltage VOUT is the differential voltage between the two output nodes OUT1 and OUT2. The second transistor T2′ of the first differential pair is also coupled to the first output node OUT1. The MOSFET transistors NM1, NM1′ and NM2 are coupled by their gates to a bias voltage VBIAS and serve as current sources for the respective stages of the circuit.

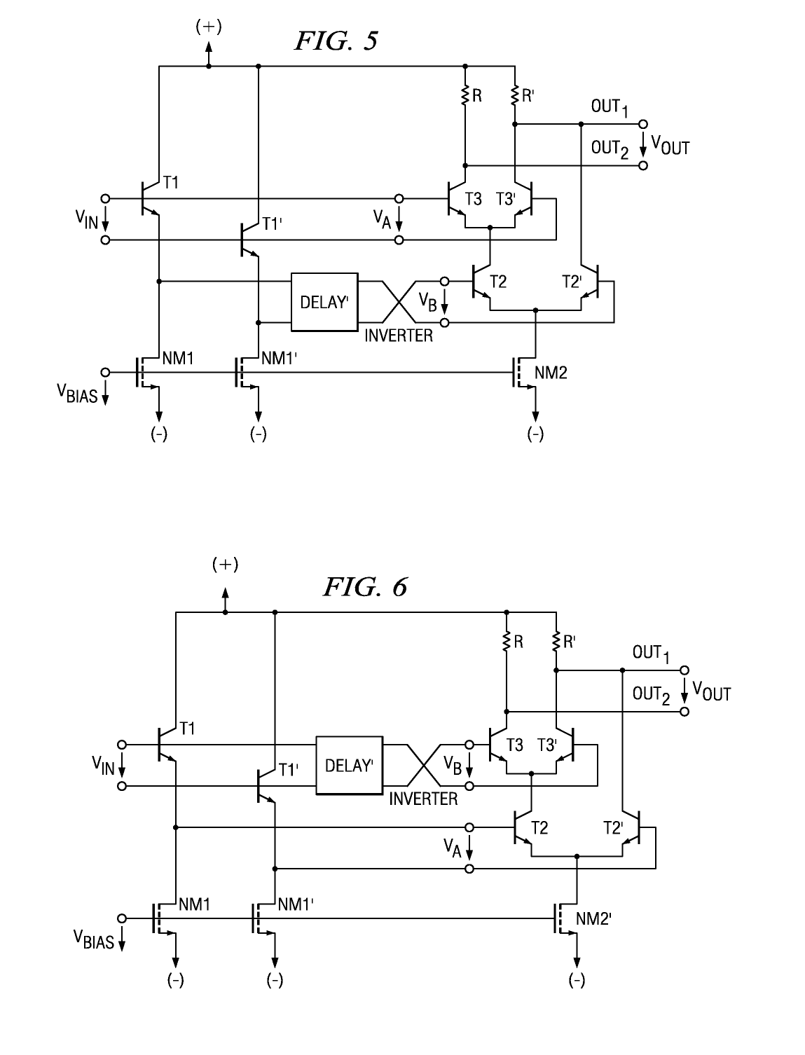

FIG. 5 shows a simplified schematic of a first embodiment of the invention. The circuit shown in FIG. 5 relates to the circuits shown in FIGS. 3A-C and is basically a differential BICMOS current mode implementation. A delay element DELAY′ and an inversion stage INVERTER are coupled between the level shifter T1, T1′ and the first differential pair T2, T2′. The input signals VB of the first differential pair T2, T2′ and the input signal VA of the second differential pair T3, T3′ relate to the corresponding signals VA and VB shown in FIGS. 3A-C. The input signal VB of the first differential pair T2, T2′ is a delayed and inverted version of the input signal VIN, whereas VA is directly connected to VIN. The output signal VOUT derived from the output nodes OUT1 and OUT2 produces a positive pulse concurrently with the rising edge of the input signal VA. VA is a slightly delayed version of VIN, such that the rising edge of the output pulse occurs at the same time as the rising edge of a respectively delayed input signal. Such a delay can be applied to the input signal VIN by a delay buffer, like the one shown in FIG. 2. The MOSFET transistors NM1, NM1′ and NM2 are biased to sink the respective currents for the stages of the circuit shown in FIG. 5.

FIG. 6 shows a differential current mode implementation of the embodiment shown in FIG. 3B. The delay elements DELAY′ and the inversion stage INVERTER are now coupled between the input receiving the input signal VIN and the input VB of the second differential pair T3, T3′. The level shifted input signal VIN is coupled to VA of the first differential pair T2, T2′. The output signal VOUT is derived from output nodes OUT1, OUT2 and will provide a positive pulse concurrently with the rising edge of the input signal VA. As the rising edge of the output pulse will be delayed with respect to the input signal VIN due to inherent delays of the circuit, a delay buffer should be coupled to the input signal as shown in FIG. 2, in order to produce delays concurrently to the rising edges of the input signal.

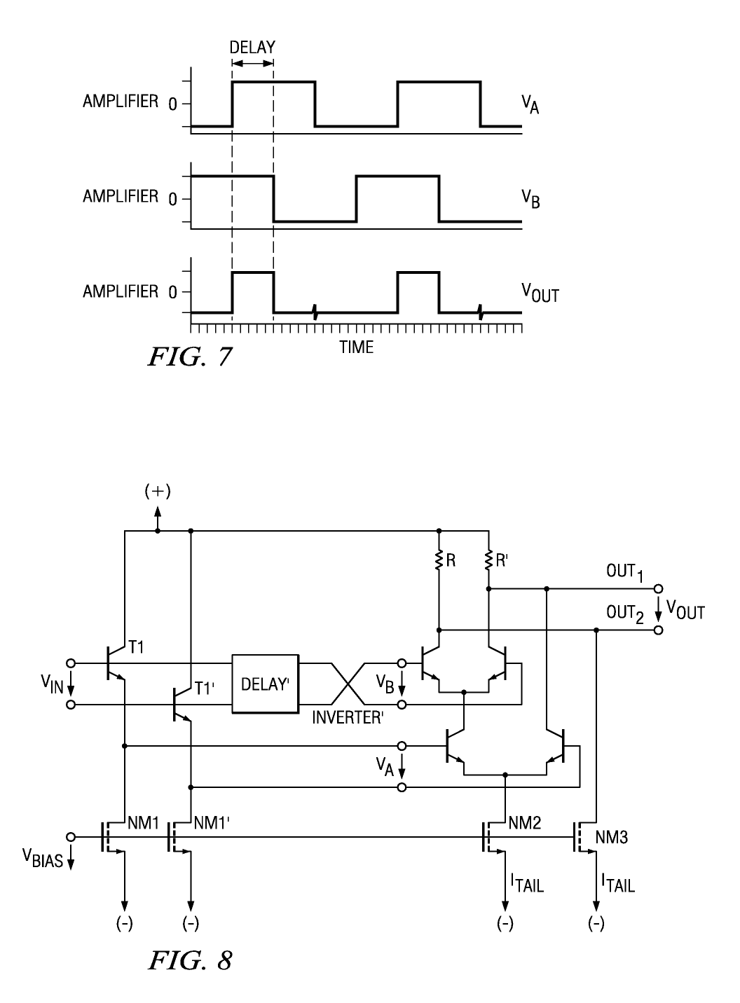

FIG. 7 shows example waveforms for the circuits shown in FIGS. 5 and 6. The input signal VB is a delayed and inverted version of input signal VA. Combining the signals VA and VB produces a pulse of a pulsewidth which corresponds to the delay introduced by the delay element DELAY′.

FIG. 8 shows a schematic of another embodiment of the invention. The circuitry is similar to the one shown in FIG. 6, except that an additional MOSFET transistor NM3, which operates as a current sink, is coupled to the output node OUT2. The additional current sunk by the current source represented by NM3 is used to shift the common mode level. Further, providing an additional current sink coupled to an output node can assure a return-to-zero of the output in-between the gated peaks. The tail current ITAIL is used to adjust the height of the pulses. The width of the pulses is adjusted by the delay of the delay element.

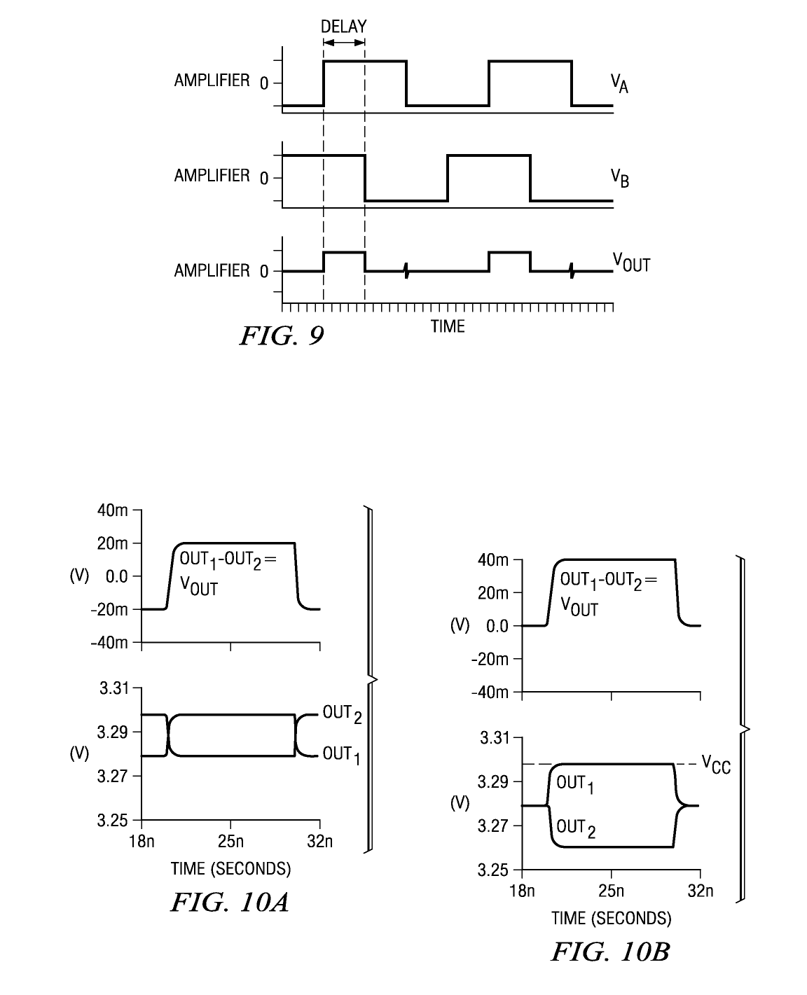

FIG. 9 shows waveforms like those shown in FIG. 7, but for the improved circuit of FIG. 8. As can be seen, the pulses of the output voltage VOUT toggle between 0V and a positive voltage level. Compared to the waveforms shown in FIG. 7, the output voltage VOUT is shifted by a positive voltage of half the amplitude of the output signal.

FIGS. 10A and B show waveforms for the embodiments shown in FIGS. 5 and 8. The waveforms of FIG. 10A relate to FIG. 5, whereas the waveforms of FIG. 10B relate to FIG. 8. As seen, the output voltage VOUT is shifted by half the amplitude (about 20 mV) by the additional current source shown in FIG. 8.

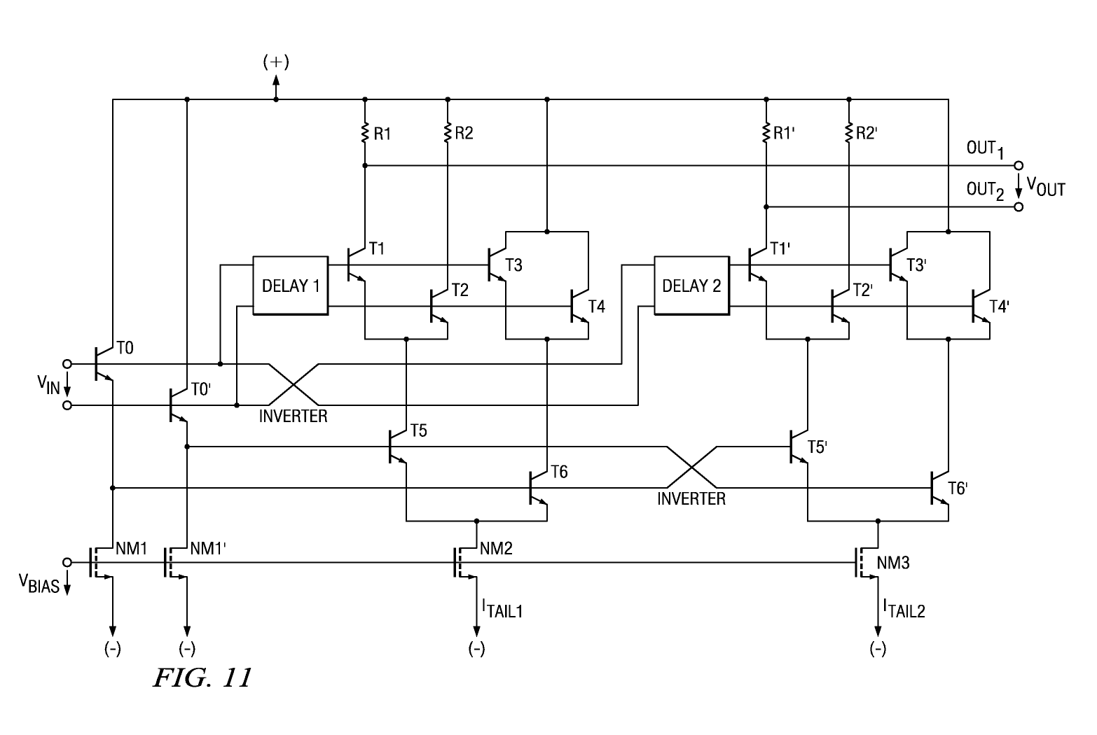

FIG. 11 shows a complete pulse generation stage in a current mode configuration for positive and negative pulses according to an embodiment of the invention. The input signal VIN is passed by level shifter T0, T0′ to transistors T5, T6 (first pair of transistors) and through an additional inversion stage INVERTER to transistors T5′ and T6′ (third pair of transistors). Further, the input signal is delayed by delay element DELAY 1 and coupled to a second pair of transistors T1, T2. The negative output pulses are produced by the differential pair T5′, T6′ and T1′, T2′. Basically, two of the above-described peak gating circuits (as for example, the circuits shown in FIGS. 5 and 8) are used to generate peaks at both edges of an input signal. Merely combining two stages like those of FIGS. 5 and 8 would result in redundant components. The output signal VOUT of the complete cell is derived from two single-ended outputs OUT1 and OUT2 from the two different stages. Therefore, no common word correction is necessary as the one described with respect to FIG. 8. The resistors R2 and R2′, as well as the transistors T3, T4, T3′ and T4′, are not required for the basic functionality. The collectors of T2, T2′, T6 and T6′ may also be directly connected to the positive supply voltage. The purpose of the additional elements R2, R2′, T3, T4, T3′ and T4′ is to assure the same collector emitter voltage drop across transistors T1 and T2 (also T1′ and T2′) as well as the cross-transistors T5 and T6 (as well as T5′ and T6′) in order to improve the high frequency transient behavior of the stage.

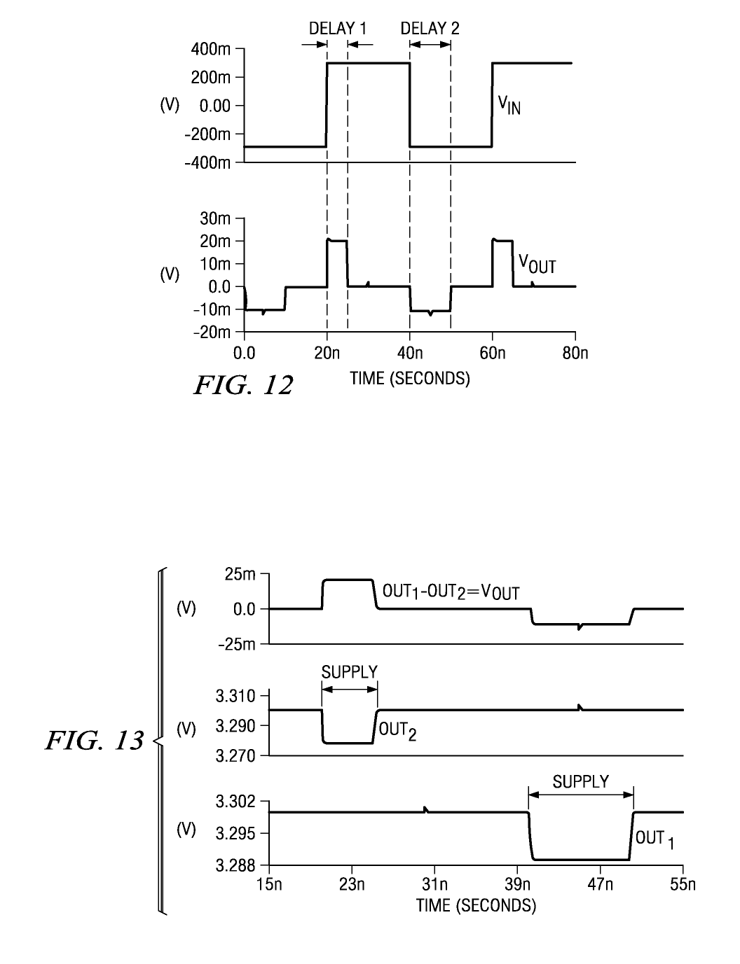

FIGS. 12 and 13 show example waveforms for the circuitry shown in FIG. 11. The delay stages DELAY 1 and DELAY 2 allow independent control of the related burst widths (over- or undershoot), while individual control of the tail current ITAIL1 and ITAIL2 assures independent adjustment of the pulse heights (over- or undershoot heights). As the load resistors R2 and R2′ are not connected to the output loads OUT1 or OUT2, no superimposed voltage drop is needed to assure an output signal that returns to differential zero in-between the bursts (over- and undershoot) as shown in FIG. 13.

Those skilled in the art to which the invention relates will appreciate that the described embodiments are merely illustrative examples, and that there are many other ways, and variations of ways, to implement the principles of the claimed invention.

What is claimed is:

1. A driver for a semiconductor light emitting device, such as a vertical cavity surface emitting laser (VCSEL), comprising:
a delay buffer for generating an output signal as a delayed version of an input signal;
a pulse generation stage coupled in parallel with the delay buffer and adapted to produce selectively positive and negative output pulses starting concurrently with respective positive and negative edges of the output signal of the buffer; and
a summer for summing the output signal and the pulses.

2. The driver according to claim 1, wherein the pulse generation stage comprises an AND gate, an inverter and a delay stage; the delay stage and the inverter being coupled in series between the input of the pulse generation stage and an input of the AND gate.

3. The driver according to claim 1, wherein the pulse generation stage comprises a NAND gate, an inverter and a delay stage; the inverter being coupled between the input of the pulse generation stage and a first input of the NAND gate, and the delay stage being coupled between the input of the pulse generation stage and a second input of the NAND gate.

4. The driver according to claim 1, wherein the pulse generation stage comprises a NOR gate, an inverter and a delay stage; the inverter being coupled between the input of the pulse generation stage and a first input of the NOR gate, and the delay stage being coupled between the input of the pulse generation stage and a second input of the NOR gate.

5. The driver according to claim 1, wherein the pulse generation stage has a differential architecture coupled in current mode, and comprises a level shifter, a first pair of transistors, a second pair of transistors, a delay element, and a signal inversion stage;
the first and the second pair of transistors being coupled so as to provide a logical NAND function for the two differential inputs of the first and the second pair.

6. The driver according to claim 5, wherein the delay stage and the signal inversion stage are coupled in series between the input and the first transistor pair, and the output of the level shifter is coupled to the second transistor pair.

7. The driver according to claim 5, wherein the input signal is supplied to the level shifter and to the first transistor pair, and the delay stage and the signal inversion stage are coupled in series between the output of the level shifter and the second transistor pair for feeding the level-shifted, delayed and inverted input signal to the second pair.

8. The driver according to claim 6, wherein a current source is coupled to an output of the pulse generation stage in order to adjust the common mode level of the differential output signal.

9. The driver according to claim 6, further comprising a second delay stage, a second signal inversion stage, a third pair of transistors and a fourth pair of transistors; the second delay stage being coupled between the input and the third transistor pair, and the second signal inversion stage being coupled between the second transistor pair and the level shifter.

10. The driver according to claim 1, implemented in a bipolar technology.

11. The driver according to claim 5, implemented in a bipolar technology; wherein the first and the second pair of transistors implement a logic NAND gate; wherein the collector of one transistor of the second transistor pair is connected to the common emitters of the first pair, the common emitters of the first pair are connected to a current source, in particular a biased MOSFET transistor, and the collectors of the second pair of transistors are connected to two respective loads in particular two resistive elements, thereby providing differential output nodes between the loads and the collectors; and wherein the collector of the second transistor of the first pair of transistors is also coupled to one output node of the differential output nodes.

12. The driver according to claim 9, implemented in a bipolar technology and further comprising a fifth pair of transistors coupled in parallel to the second pair of transistors, and a sixth pair of transistors coupled in parallel to the fourth pair of transistors; each of the second, the fifth, the fourth and the sixth pair of transistors having emitters coupled together and each of the transistor pairs being coupled to a collector of one of the transistors of the first pair of transistors and the third pair of transistors.

13. The driver according to claim 11, wherein the level shifter comprises two bipolar transistors each coupled to a respective current sink.
